(19) United States
(12) Patent Application Publication
(10) Pub. No.: US 2010/0270614 A1
(43) Pub. Date: Oct. 28, 2010

(54) PROCESS FOR MANUFACTURING DEVICES FOR POWER APPLICATIONS IN INTEGRATED CIRCUITS

(75) Inventors: Giuseppe CROCE, Missaglia (IT); Paolo GATTARI, Milano (IT); Andrea PALEARI, Arcore (IT); Alessandro DUNDULACHI, Vimercate (IT)

Correspondence Address: GRAYBEAL JACKSON LLP, 400 - 108TH AVENUE NE, SUITE 700, BELLEVUE, WA, 98004, US

(73) Assignee: STMICROELECTRONICS S.R.L., Agrate Brianza (IT)

(21) Appl. No.: 12/765,659

(22) Filed: Apr. 22, 2010

(30) Foreign Application Priority Data
Apr. 22, 2009 (IT) MI2009A000672

(51) Int. Cl. H01L 27/04; H01L 21/336; H01L 29/78; H01L 29/06; H01L 21/762

(52) U.S. Cl. 257/337; 438/297; 257/335; 257/509; 438/286; 257/E21.552; 257/E21.417; 257/E29.261; 257/E29.02; 257/E27.01; 257/341; 257/343

(57) ABSTRACT

An embodiment method for forming a MOS transistor for power applications in a substrate of semiconductor material, said method being integrated in a process for manufacturing integrated circuits which uses an STI technique for forming the insulating regions. The method includes the phases of forming an insulating element on a top surface of the substrate and forming a control electrode on a free surface of the insulating element. The insulating element insulates the control electrode from the substrate. Said insulating element comprises a first portion and a second portion. The extension of the first portion along a first direction perpendicular to the top surface is lower than the extension of the second portion along such first direction. The phase of forming the insulating element comprises generating said second portion by locally oxidizing the top surface.

### PRIORITY CLAIM

The instant application claims priority to Italian Patent Application No. MI2009A000672, filed Apr. 22, 2009, which application is incorporated herein by reference in its entirety.

### TECHNICAL FIELD

An embodiment of the present invention relates to the integrated circuits, and particularly relates to a process for manufacturing power devices in integrated circuits.

### BACKGROUND

The great majority of integrated circuits that are currently manufactured are formed by field effect transistors of the Metal-Oxide-Semiconductor type (MOS), which are produced by means of complementary manufacturing processes (CMOS). At the present time, by means of an optimized CMOS manufacturing process, it is possible to produce fast switching transistors with a high integration density.

The operative voltages managed by the MOS transistors forming an integrated circuit have values which depend on the use to which the integrated circuit itself is destined. In the integrated circuits for digital applications, such operative voltages have relatively low values, for example included in an amplitude range equals to 1.2-1.8 Volts. In the power applications—such as in the driving circuits for computer and printer motors, or in the audio amplifier circuits—such amplitude range may sensibly increase, and exceed 20 Volts.

The MOS transistors employed in power applications are structured in such a way to be capable of managing voltages having a high value without being affected by damaging or breaking, and sourcing high current values in an efficient way, minimizing the resistive drop across the terminals thereof. Among the MOS transistors for power applications presently available on the market which are capable of managing high voltages, there are enumerated the so-called Drift-MOS (DMOS) transistors, the Double Diffused MOS (DDMOS) transistors and the Drain Extended MOS (DEMOS) transistors. Such transistors have in common the presence of an extended collection region characterized by a relatively low doping level (e.g., 10¹⁶ cm⁻³-10¹⁷ atoms/cm⁻³); within said region, denoted with the term of drain extension region, a highly doped (e.g., 10²⁰ atoms/cm⁻³) contact region is formed. The drain extension region forms a junction of the n-/p type with the body region of the transistor wherein the channel is formed. This junction is reverse-biased during the normal operative conditions of the transistor, and is covered by the control electrode, which has the double function of modulating the amount of electric current flowing in the channel when the transistor is on, and extending the electric field lines of the abovementioned junction when the transistor is off, for the purpose of increasing the operative voltage which can be tolerated by the device.

Without descending into known details, all the transistors of such type exhibit an asymmetric structure, due to the presence of the drain extension region; particularly, the electric field which is formed close to the junction between the drain extension region and the region wherein the channel is formed in response to the application of high voltage differences is able to distribute itself along a longer path. As a consequence, a transistor for power applications exhibits a relatively low channel resistance when it is in conduction, and a high breakdown voltage.

In order to reduce the manufacturing costs and the silicon area occupation, both MOS transistors for power applications adapted to manage high operative voltages and high integration density MOS transistors designed for managing reduced operative voltages may be integrated on a same silicon chip. For example, a single chip may integrate a driving circuit for a motor controlled by a digital control circuit; in this case, since the digital control circuit typically has to manage low voltage signal, such circuit may be implemented by means of normal MOS transistors, while the driving circuit will be formed by MOS transistors for power applications, such as by DEMOS transistors.

In order to minimize the production costs, the manufacturing steps required for manufacturing a DEMOS transistor are typically integrated in a CMOS manufacturing flux.

For example, the drain extension region of an n-channel DEMOS transistor may be implemented forming an n-well in a region of the p type (substrate of the integrated circuit or epitaxial layer grown on the starting substrate). The source contact region is formed by means of ionic implantation of donor elements in the region of the p type (body). The drain contact region of the DEMOS transistor is formed in the end of the drain extension region opposite to the source contact region; typically, also such contact region is formed by means of ionic implantation of donor elements, and particularly at the same time of the formation of the source contact region. An insulating material layer is formed on the surface of the chip between the source contact region and the drain contact region; the gate terminal is formed by means of a conductive material layer—such as polysilicon—located above such insulating layer.

Since during the operation of the DEMOS transistor the drain is typically brought to a voltage higher than the voltage the gate terminal is brought to, the thickness of such layer is increased close to the drain region for avoiding any occurrence of breakings in the insulating material layer. For this purpose, before the formation of the gate oxide (which in the standard MOS transistors coincides with the insulating material layer in its totality), an additional insulating region is formed in the drain extension region—and particularly close to the drain contact region—having a relatively high thickness, higher than the oxide gate thickness.

Particularly, the additional insulating region is typically implemented by means of the insulating technique used in the CMOS manufacturing processes. In the advanced CMOS processes, having minimal critical sizes lower than 0.25 μm, the additional insulating region is formed by means of the insulating technique denoted “Shallow Trench Isolation” (STI). As it is known, such technique provides for the formation of the additional insulating region by means of the formation of a trench in the silicon forming the drain extension region. Such trench is filled by depositing an insulating material layer, such as silicon dioxide. The STI technique is normally used in the modern CMOS manufacturing processes for forming the insulating zones between adjacent MOS transistors in the digital circuits; thanks to the use of such technique, it is possible to obtain very high integration densities.

Consequently, the steps of the process required to form the additional insulating regions in the DEMOS transistors (or, more generally, in the transistor for power applications adapted to manage high voltages) may be integrated in a CMOS manufacturing process without high additional costs, it being sufficient to modify the masks used during the formation of the insulating zones between adjacent transistors for defining the position and the shape of the desired additional insulating regions.

A further potential advantage obtainable using the STI technique for the formation of the additional insulating zones regards the possibility of obtaining drain extension regions relatively extended without having to increase the planar size of the transistors. Indeed, since the STI technique is typically used for forming insulating zones between adjacent MOS transistors, an additional insulating region implemented with the STI technique extends in depth in the drain extension region by a non-negligible amount. For this reason, the path of the carriers responsible for the conduction of a DEMOS transistor of such type does not extend along a straight line, parallel to the chip surface. As a consequence, the length of the conductive path of a DEMOS transistor of such type is given by the length of the active zone of the transistor (i.e., the distance between the drain contact region and the source contact region) plus the vertical extension of the additional insulating region within the drain extension region (i.e., the distance between the chip surface and the bottom of the additional insulating region).

However, the use of the STI technique for the formation of transistor for power applications adapted to manage high voltages may be disadvantageous under different circumstances.

One of the most important parameters which characterize an active DEMOS transistor (i.e., when the transistor is in the conduction state, and it is crossed by current) is its electric resistance, denoted conduction resistance. Since the voltage values are high, the current flowing through an active DEMOS typically has a high value; as a consequence, it may be important that the conduction resistance is kept to a value that is as low as possible for minimizing the power dissipation in the device. However, the value of such resistance increases with the increasing of the drain extension region portion extending along the vertical direction, i.e., perpendicularly to the surface of the chip. As a consequence, using an STI technique for realizing an additional insulating region—which, as previously described, extends in depth in the drain extension region by a non-negligible amount—may increase the conduction resistance value.

A further increasing of the conduction resistance due to the use of the STI technique may be caused by a reduction of the mobility of the electrons in the silicon close to the additional insulating region. Such mobility reduction is mainly caused by the stress to which the silicon is subjected during the formation of the additional insulating regions (formation of the trenches, fill and subsequent thermal treatments).

Moreover, the lateral walls of an additional insulating region obtained by means of the STI technique extends along a direction that is substantially perpendicular to the surface of the substrate, and thus perpendicular to the trajectory traveled by the electrons injected in the channel by the source region. As a consequence, with this structure an electron provided with a sufficiently high kinetic energy (hot electron) will have a non zero probability to cross the lateral wall of the additional insulating region, and remaining trapped within the oxide field. In greater detail, the electric field that is generated in the device during the operation has a component transversal to the electron trajectory which exhibits very low values in module thanks to the particular conformation of the lateral walls; as a consequence, the electric field may not be capable of effectively opposing the injection phenomena of the carriers from the silicon to the oxide region. This phenomenon may jeopardize the conduction resistance in a negative way, and may alter the value of such resistance in a significant way.

### SUMMARY

In view of the state of the art herein illustrated, an embodiment of the present invention overcomes the above mentioned drawbacks.

Particularly, an embodiment of a method for forming a MOS transistor for power applications in a semiconductor material substrate is proposed. Such embodiment is integrated in a process for manufacturing integrated circuits which makes use of a STI technique for the formation of insulating regions. The method includes the steps of forming an insulating element on a top surface of the substrate and forming a control electrode on a free surface of the insulating element. The insulating element insulates the control electrode from the substrate. Such insulating element comprises a first portion and a second portion. The extension of such first portion along a first direction perpendicular to the top surface is lower than the extension of the second portion along such first direction. The step of forming the insulating element comprises generating such second portion by locally oxidizing the top surface.

A further embodiment provides a MOS transistor for power applications.

A still further embodiment of the present invention provides an integrated circuit.

### BRIEF DESCRIPTION OF THE DRAWINGS

One or more embodiments of the invention, as well as features and advantages thereof, may be best understood by reference to the following detailed description, given purely by way of a non-restrictive indication, to be read in conjunction with the accompanying drawings. In this respect, it is expressly intended that the figures are not necessary drawn to scale and that, unless otherwise indicated, they are merely intended to conceptually illustrate the structures and procedures described herein. Particularly:

FIG. 1 schematically shows a sectional view of an n-channel DEMOS transistor according to an embodiment of the present invention, and

FIGS. 2A-2N illustrate several phases of a process for manufacturing the DEMOS transistor illustrated in FIG. 1 according to an embodiment of the present invention.

### DETAILED DESCRIPTION

In the following of the present description, similar or identical elements illustrated in different figures will be identified with the same references. Moreover, the impurity concentrations (electrically active doping elements) included in the semiconductor materials are quantified in an indicative way by adopting the following conventions: with the terms “p” and “n” are indicated materials with an “average” concentration of acceptors and donors, respectively, with the terms “p-” and “n-” are indicated materials with a “light” concentration of acceptors and donors, respectively, while with the terms “p+” and “n+” are indicated materials with a “high” concentration of acceptors and donors, respectively.

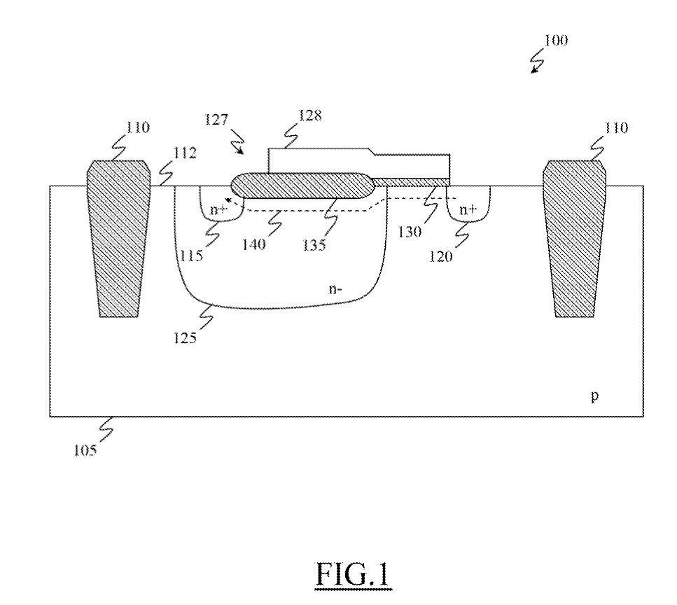

With reference to FIG. 1, a sectional view of an n-channel DEMOS transistor 100 obtainable with a manufacturing process according to an embodiment of the present invention is illustrated.

The DEMOS transistor 100 is integrated in a chip of semiconductor material, for example silicon. In the same chip may be integrated also transistors of different type (not illustrated in the figure), such as MOS transistor for low voltage digital applications, complementary bipolar transistors (NPN and PNP) and passive components (resistors, diodes and capacitors). With the reference 105 it is indicated a portion of the chip acting as a substrate (body) for the DEMOS transistor 100. The substrate 105 is formed by p-doped silicon.

The DEMOS transistor 100 may be insulated from the other devices integrated in the chip by means of insulating regions 110 formed by insulating material, such as silicon oxide (field oxide), which extends in depth in the substrate 105 starting from the top surface, identified with the reference 112. For example, the insulating region 110 may be realized by means of the STI technique described above.

The DEMOS transistor 100 comprises a drain contact region 115 and a source contact region 120, both formed by doped silicon of the n+ type. Particularly, while the source contact region 120 is directly formed in the substrate 105 (of the p type)—or in a dedicated region of the p type implanted in the substrate, the drain contact region 115 is formed within a drain extension region 125 formed by silicon of the n-type.

An insulating element 127 formed by silicon oxide is located on the surface 112 between the drain contact region 115 and the source contact region 120. The insulating element 127 is at least partially covered by a gate electrode 128 formed by a semiconductor or conductor material layer—such as properly doped polycrystalline silicon (polysilicon).

The insulating element 127 is formed by two distinct elements having different thicknesses and functions. A first portion, indicated in the figure with the reference 130, substantially extends from a border of the source contact region 120 until reaching or covering a portion of the drain extension region 125. Such element is properly referred to as gate oxide. A second portion of the insulating element 127, identified in figure with the reference 135 and denoted with the term of additional insulating region, extends from the end of the gate oxide 130 which overlaps the drain extension region 125 until reaching the drain contact region 115.

As described above, in order to avoid the occurrence of break down in the insulating element 127, and thus the occurrence of faults in a transistor for power applications such as the DEMOS transistor 100, the thickness of the insulating element 127 close to the drain contact region 115 is made to be sufficiently high. As a consequence, while the thickness of the gate oxide 130 may be of the same order of magnitude of the thickness of the gate oxide of a MOS transistor for low voltage applications, the thickness of the additional insulating region 135 is higher. Furthermore, the shape of the additional insulating region 135 and the extension of such region within the drain extension region 125 of the DEMOS transistor 100 may be designed for the purpose of overcoming the known drawbacks which usually affect the conduction resistances of the DEMOS transistors.

Particularly, the additional insulating region 135 of the proposed DEMOS transistor 100 may extend within the drain extension region 125 to a lower depth compared to the depth reached by an equivalent additional insulating region obtained by means of the conventional techniques commonly used in the CMOS fabrication processes, i.e., by means of the STI technique. Furthermore, unlike the additional insulating regions obtained by means of the STI technique, the shape of the additional insulating region 135 of the proposed DEMOS transistor 100 may be tapered at the lateral ends, i.e., at the ends which are near or in contact with the portion 130 and with the drain contact region 115.

When the bias voltage applied to the gate electrode 128 is sufficiently high, in the substrate portion 105 beneath the gate oxide 130 a conduction channel allowing the passage of current (electrons) between drain and source is formed in the p region. By properly biasing the drain contact region 115 and the source contact region 120 in such a way that the former is at an electric potential higher than that of the latter, the conduction channel is crossed by a flux of electrons flowing from the region at lower potential (the source contact region 120) toward the region at higher potential (the drain contact region 115).

An example of the path traveled by the electrons is illustrated in FIG. 1 with the reference 140. As can be observed in the figure, the path 140 does not exhibit any hard change along the direction perpendicular to the surface 112, and does not excessively penetrate in depth in the drain extension region 125, substantially remaining parallel to the surface 112. These features, due to the peculiarity of the shape and of the position of the additional insulating region 135, may positively affect the electric characteristics of the conduction channel, which has a conduction resistance having a lower and more stable value compared to the values of the conduction resistances of the known DEMOS transistors 100 wherein the additional insulating regions are obtained by means of the STI technique. Particularly, the value of the conduction resistance of the proposed DEMOS transistor 100 may be lower than in the known cases, since the path 140 which the electrons traverse has fewer vertical portions (i.e., along the direction perpendicular to the surface 112). Moreover, the value of the conduction resistance may be more stable, since the lateral walls of the additional insulating region 135 are not totally perpendicular to the surface 112—and thus to the path 140 traveled by the electrons, and consequently it may be more difficult for a hot electron to succeed in injecting to the oxide of the additional insulating region 135. Moreover, the hot-electron injection may be hindered by the conformation assumed by the electric field lines generated by the non-perpendicular lateral walls, since such electric field lines tend to have a component that is transversal to the trajectory of the electrons, which tends to reject them from the additional insulating region 135.

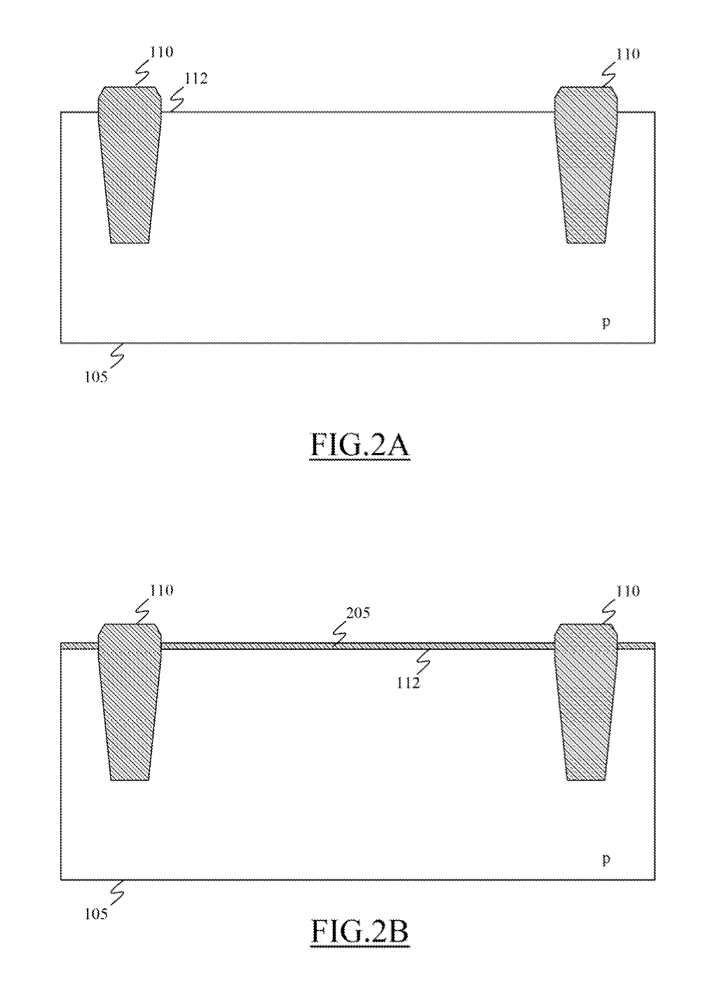

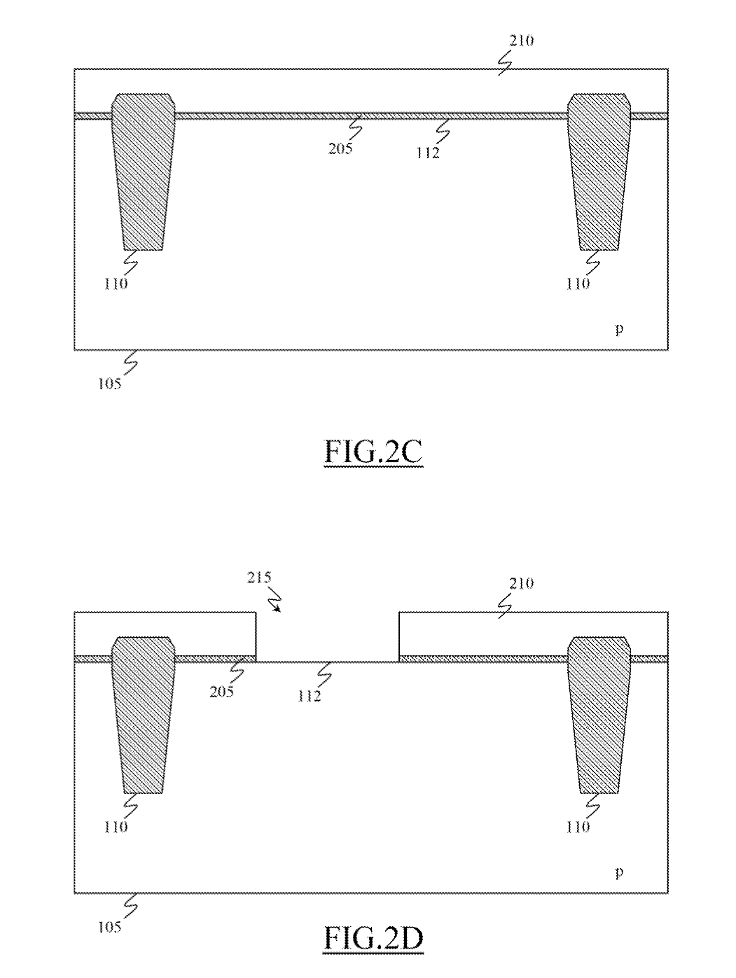

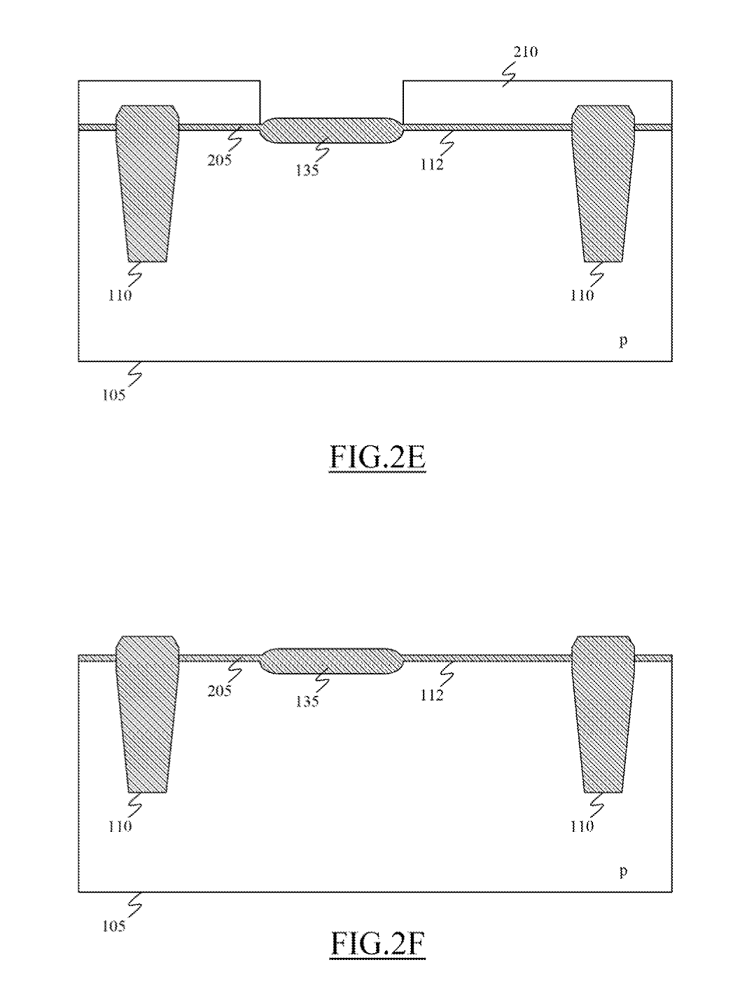

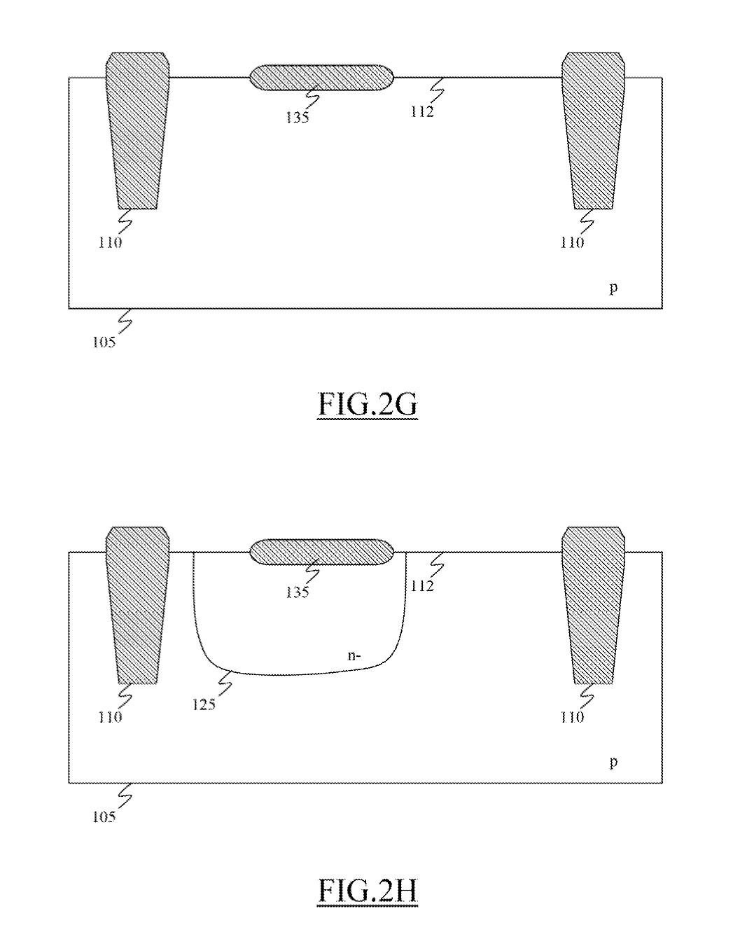

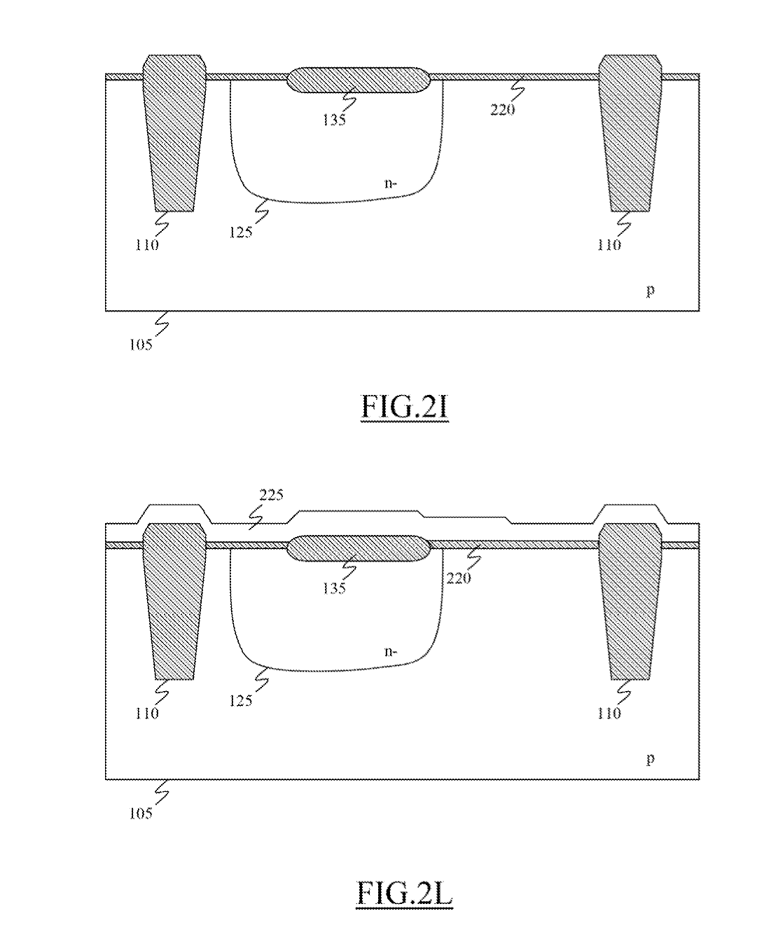

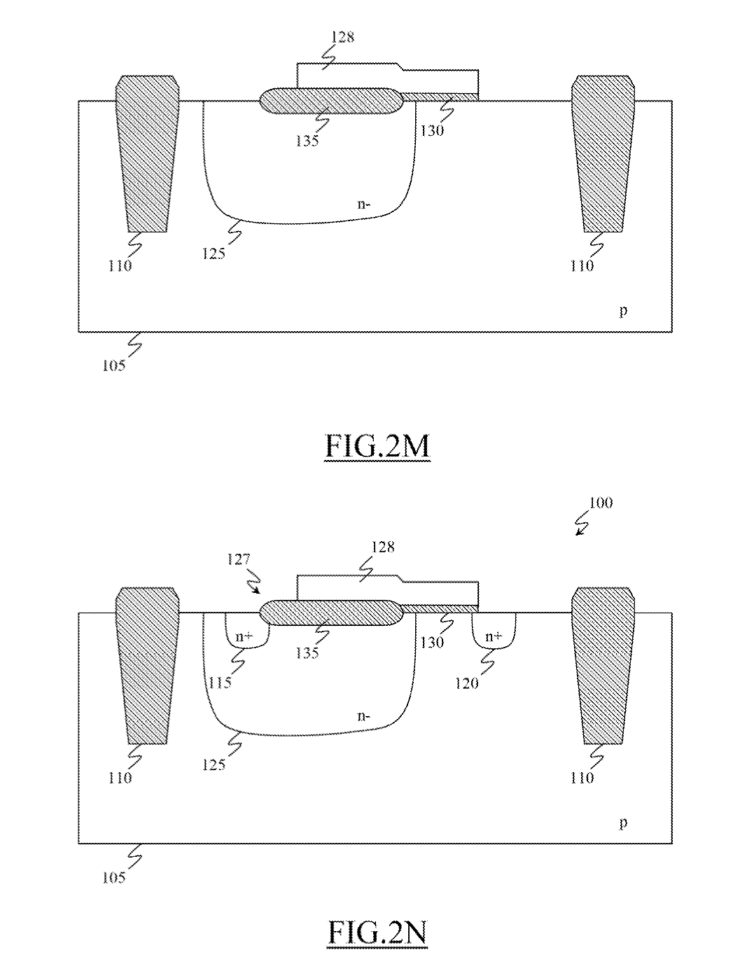

Making reference to the FIGS. 2A-2N, some phases of a process for manufacturing the DEMOS transistor 100 on a semiconductor chip according to an embodiment of the present invention will be now described. Typically, on a same chip of semiconductor material will be integrated also electronic devices of different type, such as for example MOS transistors for digital applications that manage low voltages or other components, both active and passive. In this regard, the phases which will be described in the following may be easily integrated in the process flux required for the production of the latter. Particularly, the phases illustrated in the FIGS. 2A-2N are integrated in a manufacturing process which makes use of the STI technique for the formation of the insulating regions between adjacent devices, such as a standard CMOS fabrication process.

The FIG. 2A schematically shows a sectional view of the portion 105 of the semiconductor material chip acting as a substrate for the DEMOS transistor 100 during a phase of the manufacturing process subsequent to the formation of the insulating regions 110. The insulating regions 110 are formed by means of an STI technique, in the same way as the insulating regions for insulating the transistors formed by means of a standard CMOS manufacturing process are formed. The substrate 105 is characterized by a p-type conductivity, obtained by doping the silicon of the chip by means of atoms of an acceptor element.

In the subsequent phase, illustrated in FIG. 2B, a thin silicon dioxide layer 205 is deposited on the top surface 112 of the chip, for example by means of Chemical Vapor Deposition (CVD) or through a thermal oxidation process. The layer 205, in jargon denoted protection oxide, is a protective layer which has the function of protecting the underlying substrate 105 from excessive stresses which may occur during the subsequent phases of the manufacturing process. According to an alternative embodiment of the present invention, instead of forming the protection oxide 205 by means of CVD, it is possible to reuse one of the oxide layers which have been employed during preceding process phases, which normally would be selectively removed. For example, since the insulating regions 110 have been formed by means of the STI technique, which may be carried out protecting the surface of the substrate by means of an oxide protective layer, such oxide protective layer, which normally is removed once the insulating regions are formed, may by also exploited as protection oxide 205 for the phases subsequent to that illustrated in FIG. 2B.

Then, as illustrated in FIG. 2C, a silicon nitride sacrificial layer 210 is deposited on the top surface of the chip by means of CVD, in such a way to cover both the protection oxide 205 and the insulating regions 110.

At this point, a window is opened in the silicon nitride sacrificial layer 210 by means of the execution of lithographic masking and selective attacking operations. Particularly, as illustrated in FIG. 2D, by exploiting a dedicated mask (not shown in the figure), a portion of the silicon nitride sacrificial layer 210 located between the insulating regions 110 and the underlying portion of protection oxide 205 are attacked and removed for generating a window 215, and for baring a corresponding portion of the top surface 112. The previously described removal of the protection oxide 205 is an optional phase of the proposed embodiment, since such layer may be only partially removed or may be maintained thanks to the selectivity of the silicon nitride attack without compromising the formation of the global structure.

The window 215 is used for defining the additional insulating region 135 of the DEMOS transistor 135. Particularly, the length of the window 215 determines the length of the additional insulating region 135; such length may vary according to the voltage the DEMOS transistor 100 may have to manage during the operation. As illustrated in FIG. 2E, according to an embodiment of the present invention, the additional insulating region 135 is formed by means of thermal oxidation of the silicon forming the substrate 105. Specifically, the chip is subjected to a Local Oxidation of Silicon (LOCOS) operation, by means of which the superficial surface of the substrate 105 which is not covered by the sacrificial layer 210 is oxidized, originating a silicon oxide layer which will constitute the additional insulating region 135 of the DEMOS transistor 100. The presence of the protection oxide 205 may prevent the occurrence of possible defects in the substrate 105 caused by the unavoidable mechanical stresses (induced by the nitride layer deformation) to which the substrate 105 is subjected during the high temperature thermal treatment required for forming the insulating region 135. The nitride layer 210 further prevents the oxidation of the substrate portions 105 close to the STI insulating regions, avoiding the occurrence of crystallographic defects which would may be harmful for the whole operation of the transistor.

By means of a conventional LOCOS technique, it is possible to generate a silicon oxide layer with a controlled thickness, which extends in depth in the substrate 105 by a relatively low amount. Thus, thanks to the proposed embodiment it may be possible to form a relatively thin additional insulating region 135, which extends in depth in the substrate 105 by a lower amount compared to an additional insulating region obtained by means of an STI technique. At the current technological state, an insulation region 135 obtained by means of the STI technique may extend in depth in the substrate by a relatively high depth; forming instead the additional insulating region 135 by means of the LOCOS technique such in depth extension may be reduced to about one third. Since the proposed additional insulating region 135 is formed by means of the LOCOS technique, the lateral ends of the oxide layer which form the region may exhibit a tapered shape—in jargon, “bird's beak”. As already mentioned, such features of the additional insulating region 135 provide a DEMOS transistor with a better channel resistance, i.e., more stable, having a lower value. Moreover, thanks to the proposed embodiment, the silicon portion underneath the additional insulating region 135 (and thus corresponding to a portion of the channel) may not be subjected to excessive stress during the manufacturing process, since, unlike the STI technique, the LOCOS technique does not require the generation of trenches within the substrate. In this way, few to no interruptions are formed in the crystalline lattice, avoiding a significant negative affect on the carrier mobility.

Subsequently, as illustrated in FIG. 2F, the silicon nitride sacrificial layer 210 is totally removed. At this point, the manufacturing process may provide for the formation of n and p type wells by means of ionic implantation, usable for the formation of possible low voltage MOS transistors, bipolar transistors and passive components (not shown in the figure).

In the following phase, illustrated in FIG. 2G, the protection oxide 205 is completely removed.

As illustrated in FIG. 2H, once the protection oxide 205 has been removed, the drain extension region 125 may be defined in the substrate 105 portion underneath the additional insulating region 135, for example by means of ionic implantation of a donor element. The formation of the drain extension region 125 may be also carried out in a different moment of the process flux, such as before the removal of the protection oxide 205.

At this point, in order to complete the insulating element 127 of the DEMOS transistor 100 (see FIG. 1) The embodiment proceeds to the formation of the gate oxide 130. The gate oxide 130 may be formed in the same way as the gate oxides for MOS transistors for low voltage applications are normally formed, i.e., by growing (by means of a thermal oxidation process) an oxide layer of proper thickness on the surface of the chip—indicated in FIG. 2I with the reference 220-, and selectively etching such layer in a subsequent phase. Without descending into conventional details, the final thickness of the gate oxide 130 may be obtained with a single oxidizing operation or with a proper sequence of oxidizing/masking operations, as in the manufacturing processes with diverse oxides.

Thanks to the previously described operations, it is possible to form an insulating element 127 having a differentiated thickness for the correct operation of a DEMOS transistor for high power applications. Particularly, the thickness of the gate oxide 130 is determined by the thickness of the oxide layer 220 grown in the phase of the manufacturing process illustrated in FIG. 2I, while the thickness of the additional insulating region 135 is determined by the characteristics of the oxidation process exploited in the phase illustrated in FIG. 2E.

In the following phase, illustrated in FIG. 2L, the chip is covered by a semiconductor or conductor layer, such as polysilicon. The polysilicon layer 225 is then defined by means of masking operations, and subjected to selective etching operations. In this way there are defined both the gate electrode 128 and the underlying gate oxide 130, as illustrated in FIG. 2M.

The FIG. 2N illustrates the complete structure of the DEMOS transistor 100, after the definition of the drain contact region 115 and of the source contact region 120. The definition of such regions may be carried out at the same time of the definition of the drain and source contact regions of possible MOS transistors for low voltage applications which may be integrated in the same chip, and particularly carrying out ionic implantation of donor elements.

Although in the present description reference has been made to a process for manufacturing an n-channel DEMOS transistors, at least some of the same considerations may apply in the case of a p-channel DEMOS transistors, or in the case of a different MOS transistors for power applications adapted to manage high voltages, such as a DMOS or a DDMOS.

Concluding, according to an embodiment of the present invention, by means of the process phases illustrated in the FIGS. 2A-2N, it is possible to form DEMOS transistor which is not affected by the drawbacks normally affecting performances of the known DEMOS transistors formed by means of the advanced CMOS processes exploiting insulating techniques of the STI type. These process phases may be easily integrated into a standard CMOS integration process, without excessive costs. Particularly, starting from a standard CMOS integration process, it is sufficient to add the process phases illustrated in the FIGS. 2C-2G, which may use a single additional and dedicated mask, i.e., the mask used for defining the portion of the substrate to be subjected to local oxidation for generating the additional insulating region 135.

The transistor 100 and the integrated circuit on which it is disposed may be part of a system, such as the electrical system of an automobile or other vehicle.

Naturally, in order to satisfy local and specific requirements, a person skilled in the art may apply to the embodiment described above many modifications and alterations. Particularly, although the embodiments have been described with a certain degree of particularity, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a general matter of design choice.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1. A method for forming a MOS transistor for power applications in a substrate of semiconductor material, said method being integrated in a process for manufacturing integrated circuits which uses an STI technique for forming the insulating regions, said method including the following phases:
forming an insulating element on a top surface of the substrate;
forming a control electrode on a free surface of the insulating element, said insulating element insulating the control electrode from the substrate, wherein:
said insulating element comprises a first portion and a second portion, the extension of the first portion along a first direction perpendicular to the top surface being lower than the extension of the second portion along said first direction, said phase of forming the insulating element comprising generating such second portion by locally oxidizing the top surface.

2. The method of claim 1, wherein the phase of generating the second portion comprises:
forming a protective layer on the top surface;
depositing a sacrificial layer on the protective layer;
etching the sacrificial layer and the protective layer for uncovering a portion of the top surface, and
oxidizing said uncovered portion of the top surface.

3. The method of claim 1, wherein such phase of forming the insulating element comprises generating such first portion performing the following phases:
depositing an oxide layer on the top surface, and
selectively etching the oxide layer.

4. The method of claim 1, wherein the substrate is formed by silicon of a first conductivity type, the process further including:
forming in the substrate a drain region of a second conductivity type opposed to the first conductivity type and a source region of the second conductivity type, wherein:
the drain region and the source region extend in the substrate from the top surface, and
the first portion is adjacent to the source region, and the second portion is adjacent to the drain portion.

5. The method of claim 4, further including:
before the formation of the drain region and the source region, forming a drain extension region of the second conductivity type in the substrate, such forming the drain region comprising forming the drain region in the drain extension region.

6. The method of claim 1, wherein said generating the second portion by locally oxidizing the top surface comprises executing an oxidizing operation by means of a LOCOS technique.

7. A MOS transistor for power applications in a substrate of semiconductor material, said transistor including:
an insulating element located on a top surface of the substrate;
a control electrode located on the insulating element, said insulating element insulating the control electrode from the substrate, wherein:
said insulating element comprises a first portion and a second portion, the extension of the first portion along a first direction perpendicular to the top surface being lower than the extension of the second portion along such first direction, wherein said transistor is manufactured according to claim 1.

8. The transistor of claim 7, wherein the substrate is formed by silicon of a first conductivity type, the transistor further including:
a drain region of a second conductivity type opposed to the first conductivity type and a source region of the second conductivity type, and wherein:
the drain region and the source region extend in the substrate from the top surface, and
the first portion is adjacent to the source region, and the second portion is adjacent to the drain portion.

9. The transistor of claim 8, wherein the drain region is comprised within a drain extension region of the second conductivity type, which extends in the substrate from the top surface.

10. The transistor of claim 7, wherein said transistor is a transistor of the DEMOS type.

11. The transistor of claim 7, wherein the second portion exhibits a tapering in the proximity of a first and a second ends along a second direction perpendicular to the first direction.

12. A circuit integrated in a substrate of semiconductor material comprising a plurality of electronic devices, wherein said plurality of electronic devices comprises at least one MOS transistor for power application according to claim 7.

13. The integrated circuit of claim 12, wherein the electronic devices of said plurality are electrically insulated by means of insulating regions formed by means of an STI technique.

14. The integrated circuit of claim 13, wherein:
said insulating regions extend in the substrate along the first direction by a first amount, and
the second portion of the insulating element of the at least one MOS transistor for power application extends in the substrate along the first direction by a second amount, said second amount being lower than said first amount.

15. The integrated circuit of claim 14, wherein the second amount is substantially equal to a third of the first amount.

16. An electronic device, comprising:
a body region;
a first source-drain region disposed in the body region;
a second source-drain region disposed in the body region and spaced from the first source-drain region;
a gate insulator disposed over the body region between the first and second source-drain regions and having a first portion of a first thickness adjacent to the first source-drain region and having a second portion of a second thickness adjacent to the second source-drain region; and
a gate electrode disposed over the gate insulator.

17. The electronic device of claim 16 wherein:
the body region has a first type of conductivity; and
the first and second source-drain regions have a second type of conductivity.

18. The electronic device of claim 16 wherein:
the body region has a P type of conductivity; and
the first and second source-drain regions have an N type of conductivity.

19. The electronic device of claim 16 wherein the first thickness is greater than the second thickness.

20. The electronic device of claim 16 wherein the first portion of the gate insulator overlaps the first source-drain region.

21. The electronic device of claim 16 wherein the second portion of the gate insulator overlaps the second source-drain region.

22. The electronic device of claim 16 wherein the first portion of the gate insulator extends into the body region.

23. The electronic device of claim 16 wherein the first portion of the gate insulator has at least one rounded end.

24. The electronic device of claim 16, further comprising:
a source-drain extension region disposed in the body region; and
wherein the first source-drain region is disposed in the source-drain extension region.

25. The electronic device of claim 16, further comprising:
the body region has a first type of conductivity;
the first and second source-drain regions have a second type of conductivity.
a source-drain extension region disposed in the body region and having the second type of conductivity; and
wherein the first source-drain region is disposed in the source-drain extension region.

26. The electronic device of claim 16, further comprising:
a substrate; and
wherein the body region is disposed in the substrate.

27. The electronic device of claim 16 wherein the gate electrode extends over only part of the first portion of the gate insulator.

28. The electronic device of claim 16 wherein the gate electrode extends over the entire second portion of the gate insulator.

29. An integrated circuit, comprising:
a first electronic device, comprising:
a body region;
a first source-drain region disposed in the body region;
a second source-drain region disposed in the body region and spaced from the first source-drain region;
a gate insulator disposed over the body region between the first and second source-drain regions and having a first portion of a first thickness adjacent to the first source-drain region and having a second portion of a second thickness adjacent to the second source-drain region; and
a gate electrode disposed over the gate insulator.

30. The integrated circuit of claim 29 wherein the electronic device comprises a transistor.

31. The integrated circuit of claim 29, further comprising a second electronic device.

32. A system, comprising:
a first integrated circuit, comprising:
an electronic device, comprising:
a body region;
a first source-drain region disposed in the body region;
a second source-drain region disposed in the body region and spaced from the first source-drain region;
a gate insulator disposed over the body region between the first and second source-drain regions and having a first portion of a first thickness adjacent to the first source-drain region and having a second portion of a second thickness adjacent to the second source-drain region; and
a gate electrode disposed over the gate insulator; and
a second integrated circuit coupled to the first integrated circuit.

33. The system of claim 32 wherein the first and second integrated circuits are disposed on a same integrated circuit die.

34. The system of claim 32 wherein the first and second integrated circuits are disposed on respective integrated circuit dies.

35. The system of claim 32 wherein at least one of the first and second integrated circuits comprises a controller.

36. A method, comprising:
forming first and second source-drain regions in a substrate;
forming a first gate insulator having a first thickness over the substrate and between the first and second source-drain regions; and
forming a second gate insulator having a second thickness over the substrate between the first gate insulator and one of the first and second source-drain regions.

37. The method of claim 36 wherein forming the first gate insulator comprises growing the first gate insulator.

38. The method of claim 36 wherein forming the second gate insulator comprises depositing the second gate insulator.

39. The method of claim 36, further comprising forming a gate electrode over the gate insulator.

40. The method of claim 36, further comprising:
forming a source-drain extension region in the substrate; and
wherein forming the first and second source-drain regions comprises forming at least one of the first and second source-drain regions in the extension region.

41. The method of claim 36, further comprising:
forming a source-drain extension region in the substrate; and
wherein forming the first and second source-drain regions comprises forming one of the first and second source-drain regions in the extension region and forming the other of the first and second source-drain regions spaced from the extension region.

42. The method of claim 36 wherein forming the first gate insulator comprises forming at least one end of the first gate insulator such that the at least one end is not substantially perpendicular to a surface of the substrate.
